(19) United States
(12) Patent Application Publication
(10) Pub. No.: US 2015/0333474 A1
(43) Pub. Date: Nov. 19, 2015

(54) DIFFERENTIAL IMPEDANCE MATCHED LASER DIODE DRIVER WITH HYBRID AC-DC MATCH

(71) Applicant: TEXAS INSTRUMENTS INCORPORATED, Dallas, TX (US)

(72) Inventors: Raymond E. Barnett, Farmington, MN (US); Jeremy Kuehlwein, Woodbury, MN (US); Douglas Dean, Eagan, MN (US)

(21) Appl. No.: 14/601,842

(22) Filed: Jan. 21, 2015

Related U.S. Application Data
(60) Provisional application No. 61/930,228, filed on Jan. 22, 2014.

(51) Int. Cl. H01S 5/026; G11B 7/127; H01S 5/042

(52) U.S. Cl. CPC H01S 5/0261; H01S 5/042; G11B 7/127

(57) ABSTRACT

An apparatus with a differential impedance matched laser diode driver with AC-DC match.

### CROSS REFERENCE TO RELATED APPLICATIONS

This application claims the benefit of U.S. Provisional Application No. 61/930,228, filed Jan. 22, 2014, the entirety of which is hereby incorporated by reference.

### BACKGROUND

1. Technical Field

This Patent Disclosure relates generally to driver circuitry for laser diodes, such as used in a magnetic disk drive recording method called Heat Assisted Magnetic Recording, or HAMR.

2. Related Art

HAMR uses a magnetic field writer, similar to what currently writes data to the disk, in conjunction with a laser diode (LD) driver, which heats of spot on the disk to allow the magnet writer to change the magnetic flux on this disks surface. This allows for higher bit packing density, a critical parameter for advancing the next generation of the Hard Disk Drive's (HDD's).

HAMR HDD writing systems use a laser diode driver that is high speed, for example, in the range of 5 GHz or 5 Gb/s. In addition, it is advantageous for a HAMR LD driver to provide accurate laser output current, which can extend the lifetime of the laser near field transducer used to focus/shrink the spot on the disk. High accuracy and high data rate are traditional tradeoff parameters in circuit design.

A HAMR HDD writing system uses a HAMR Laser Diode Driver (LDD) and associated laser/transducer to focus a small laser spot for heating a magnetic medium. When the magnetic medium is heated sufficiently a traditional flux inducing magnetic/inductive high speed write driver can then write the media. For example, the LDD can operate at 5 GHz when the magnetic/inductive writer is operating at 5 Gb/s.

The LDD and magnetic/inductive writer are phase locked to maintain phase within a few 10's of ps over all temperature, voltage and process changes.

The LDD is interconnected to the LD over a transmission line. For example, HAMR HDD writing systems commonly use a 200 ps delay transmission line and the HAMR LDD is broadband impedance matched to this transmission line.

FIG. 1A illustrates a HAMR LDD system 10 including a single-ended LDD 11 interfaced to an LD (anode and cathode) over a transmission line (TLine) with impedance Z_{O}. LDD 11 interfaces to the TLine through a OUTP port coupled through the TLine to the LD anode. The LD cathode returns through the TLine to GND.

LDD 11 provides AC matching, and includes a high-accuracy DC current source 13, such as described in US Published Application 2013/0076266. DC current source 13 provides laser out pulses IOP, driven out by LDD 11 to provide ILASER current drive to the LD (anode). A problem with this approach is that the GND loop inductance is difficult to control, and can cause ringing and reflections that compromise AC (high frequency) match.

FIG. 1B illustrates a HAMR LDD system 20 including a differential LDD 21 interfaced to an LD (anode and cathode) over a transmission line (TLine) with impedance Z_{O}. HAMR LDD 11 drives differential laser current pulses IOP over the TLine through a differential port with OUTP (anode) and OUTN (cathode) connections to the TLine.

Differential LDD 21 provides impedance (Z_{O}) matching to the TLine. A problem with this approach is maintaining DC current accuracy when driving a series resistor (Z_{O}/2) with a voltage (VDC), given that laser diode characteristics change over temperature, or from diode to diode.

While this Background information is presented in the context of an HAMR application, this Patent Disclosure is not limited to such applications, but is more generally directed to transistor switching control.

### BRIEF SUMMARY OF THE DISCLOSURE

This Brief Summary is provided as a general introduction to the Disclosure provided by the Detailed Description and Drawings, summarizing some aspects and features of the Disclosure. It is not a complete overview of the Disclosure, and should not be interpreted as identifying key elements or features of, or otherwise characterizing or delimiting the scope of, the Disclosed invention.

The Disclosure describes a differential impedance matched laser diode driver with hybrid AC-DC matching, such as can be used in HAMR applications.

According to aspects of the Disclosure, a differential impedance matched laser diode driver with hybrid AC-DC match is suitable for driving a laser diode including an anode terminal and a cathode terminal, defining an anode side and a cathode side. A differential laser diode driver (LDD) circuit with differential OUTP and OUTN ports is coupled respectively to the anode and cathode side of the laser diode through a transmission line (TLine) characterized by an impedance Z_{O}. The LDD is configured to drive a differential ILASER current that includes a DC current and IOP current pulses, over the TLine to the laser diode, with AC and DC impedance matching to the TLine.

The LDD includes an AC current-drive and impedance-match circuit, and a DC common-mode-drive and impedance-match circuit. The AC current-drive and impedance-match circuit is coupled through the OUTP port over the TLine to the laser diode anode side, and is configured to drive the ILASER current including DC current and IOP current pulses to the laser diode anode side, impedance matched to the TLine, and including: (a) anode-side current drive circuitry coupled to the OUTP port, including DC current source circuitry, and IOP current pulse circuitry, parallel coupled to the OUTP port, and configured to drive DC current and IOP current pulses to the laser diode anode side, providing the ILASER current; and (b) AC-match circuitry coupled to the OUTP port, and configured as an AC impedance matching loop to provide AC impedance matching to the TLine. The DC common-mode-drive and impedance-match circuit is coupled through the OUTN port over the TLine to the laser diode cathode side, and is configured to set differential common mode voltage at the laser diode cathode side, impedance matched to the TLine, including: (a) DC-match common-mode circuitry coupled to the OUTN port, and configured to drive common mode voltage to the laser diode cathode side; and (b) cathode-side complementary current source circuitry coupled to the OUTN port, including DC current source circuitry, and IOP current pulse circuitry, parallel coupled to the OUTN port, and configured as a current source complementary to the anode-side current drive circuitry, to provide differential common mode voltage accuracy.

In other aspects of the Disclosure, the anode-side current drive circuitry further includes anode-side undershoot-control circuitry coupled to the OUTP port, and the cathode-side complementary current source circuitry further includes cathode-side undershoot-control circuitry coupled to the OUTN port. The anode-side and cathode-side undershoot-control circuitries are configured to provide complementary undershoot-control for the IOP current pulses driven to the laser diode, thereby controlling laser turn-off at the end of an IOP current pulse. In other aspects of the Disclosure, the anode-side IOP current pulse circuitry and the complementary cathode-side IOP current pulse circuitry are each configured to provide complementary overshoot control for respective IOP current pulses, thereby controlling rise time of the IOP current pulses. In other aspects of the Disclosure, the AC impedance matching loop is implemented with low-pass filter circuitry configured to low-pass filter the ILASER current from the anode-side current drive circuitry, proving input to a unity gain buffer coupled to the OUTP port through a matched resistor ZO/2, thereby providing AC impedance matching to the TLine. The low-pass filter circuitry can be implemented comprises an Rfb/Cfb circuit with variable Cfb to provide programmable filter time constant.

Other aspects and features of the invention claimed in this Patent Document will be apparent to those skilled in the art from the following Disclosure.

### BRIEF DESCRIPTION OF THE DRAWINGS

FIGS. 1A and 1B illustrate prior approaches to a laser diode driver such as used in HAMR applications: FIG. 1A illustrates a single-ended implementation, and FIG. 1B illustrates a differential implementation.

FIG. 2 illustrates an example embodiment of a differential impedance-matched laser diode driver with hybrid AC-DC matching, such as can be used for HAMR applications.

FIG. 3 illustrates an alternate embodiment of the differential impedance matched laser diode driver with hybrid AC-DC match, including undershoot control for fast laser turn-off.

FIG. 4 illustrates example HAMR waveforms for write operation in which an IOP current pulse is driven to a laser diode, including overshoot/undershoot pulse shaping.

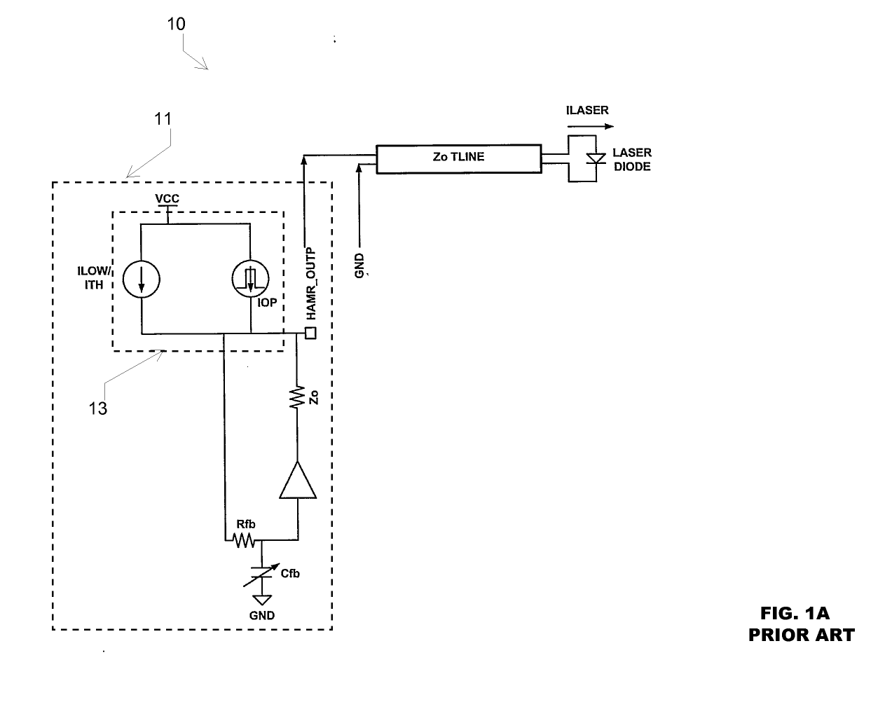

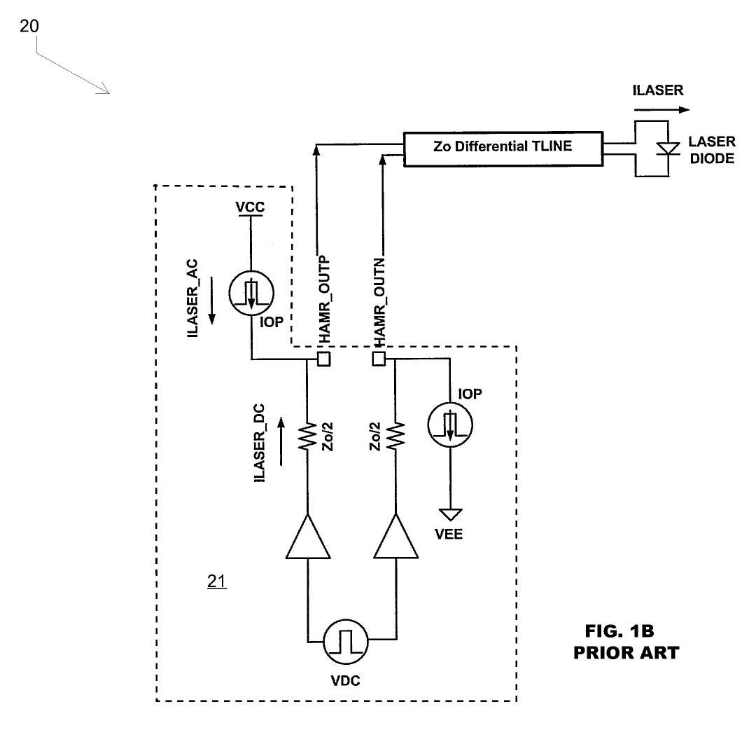

### DETAILED DESCRIPTION

This Description and the Drawings constitute a Disclosure of a differential impedance matched laser diode driver with hybrid AC-DC matching, according to the invention, including example embodiments that illustrate various features and advantages, in the context of a HAMR (Heat Assisted Magnetic Recording) application.

In brief overview, the Disclosed differential impedance matched laser diode driver with hybrid AC-DC matching can be configured with AC and DC match circuits. The AC-match circuit (anode side) drives an ILASER current including DC current and IOP current pulses, including anode-side current drive circuitry with a DC current source and IOP current pulse generator. An AC impedance matching loop provides AC impedance matching to the TLine. The DC-match circuit (cathode side) sets differential common mode voltage at the laser diode cathode side, including DC-match common-mode circuitry that drives common mode voltage to the laser diode cathode side, and a cathode-side complementary current source circuitry with DC current source and IOP current pulse generator, configured as a current source complementary to the anode-side current drive circuitry, providing differential common mode voltage accuracy. IOP current pulses can include IOS (overshoot) and IUS (undershoot) for pulse shaping.

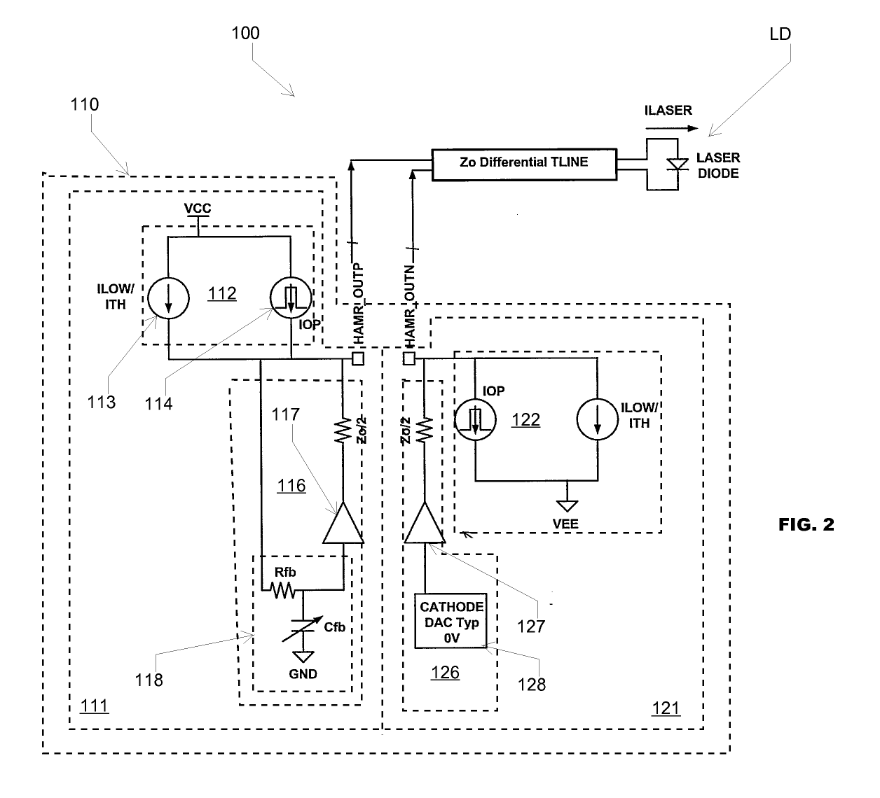

FIG. 2 illustrates an example embodiment of a differential impedance-matched laser diode driver (LDD) with hybrid AC-DC matching, such as can be used for HAMR applications. As illustrated in FIG. 2, a HAMR LDD driver system 100 is adapted for driving a laser diode LD, including anode terminal and cathode terminals, defining an anode side and a cathode side of the laser diode. HAMR system 100 includes a differential laser diode driver (LDD) 110.

LDD 110 is coupled through a transmission line TLine respectively to the anode and cathode side of laser diode LD. TLine is characterized by an impedance Z_{O}. For example, TLine can be a 200 ps time delay transmission line with characteristic impedance from 25 to 50 ohms differential.

LDD 110 is configured to drive a differential ILASER current, with a DC current and IOP current pulses, over TLine to laser diode LD, with AC and DC impedance matching to the TLine.

LDD 110 includes an AC current-drive and impedance-match circuit 111, and DC common-mode-drive and impedance-match circuit 121. AC current-drive and impedance-match circuit 111 is coupled through the HAMR_OUTP port over the TLine to the anode side of laser diode LD. DC common-mode-drive and impedance-match circuit is coupled through the OUTN port over the TLine to the laser diode cathode side.

AC current-drive and impedance-match circuit 111 is configured to drive the ILASER current including DC current (ITH/ILOW) and IOP current pulses to the laser diode anode side, impedance matched to the TLine. AC current-drive and impedance-match circuit 111 includes anode-side current drive circuitry 112, and AC-match circuitry 116, both coupled to the HAMR_OUTP port.

Current-drive circuitry 112 includes DC current source 113 and IOP current pulse generator 114, parallel coupled to the OUTP port. Current-drive circuitry 112 drives DC current and IOP current pulses to the laser diode anode side, providing the ILASER current.

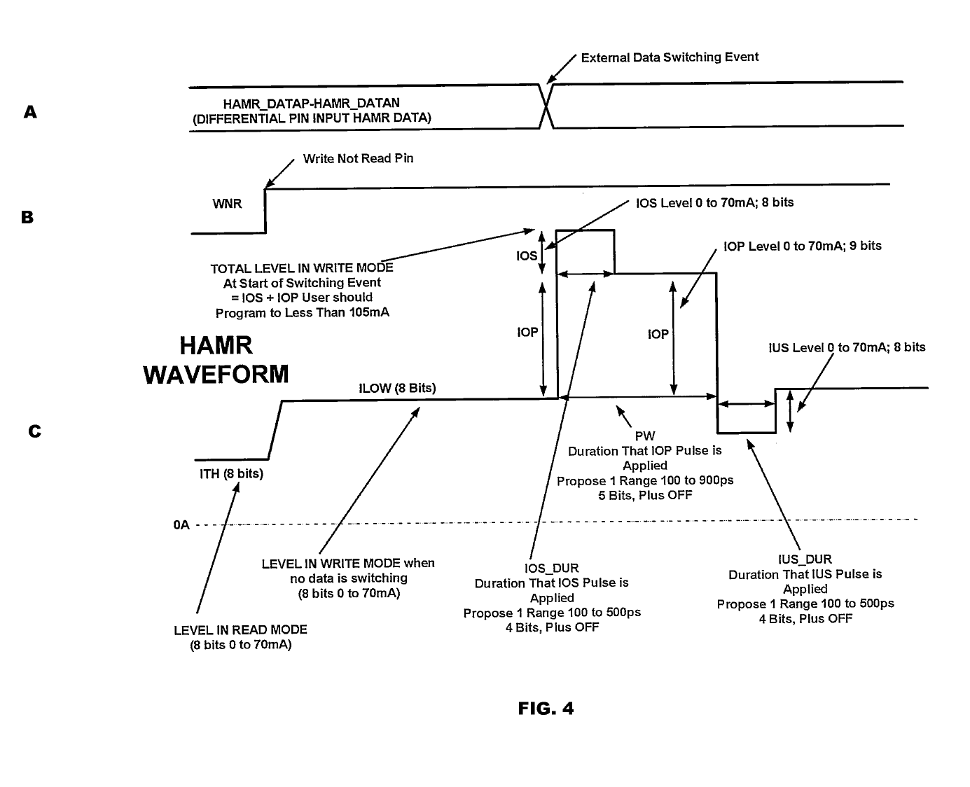

For the example HAMR application of LDD 110, DC current source 113 is configured to generate ITH and ILOW DC currents. As further described in connection with an example HAMR waveform in FIG. 4, ITH is a threshold DC level supplied to the laser diode level during read operations. When LDD 110 is switched to write mode, DC current source 113 transitions to drive a standby DC current ILOW.

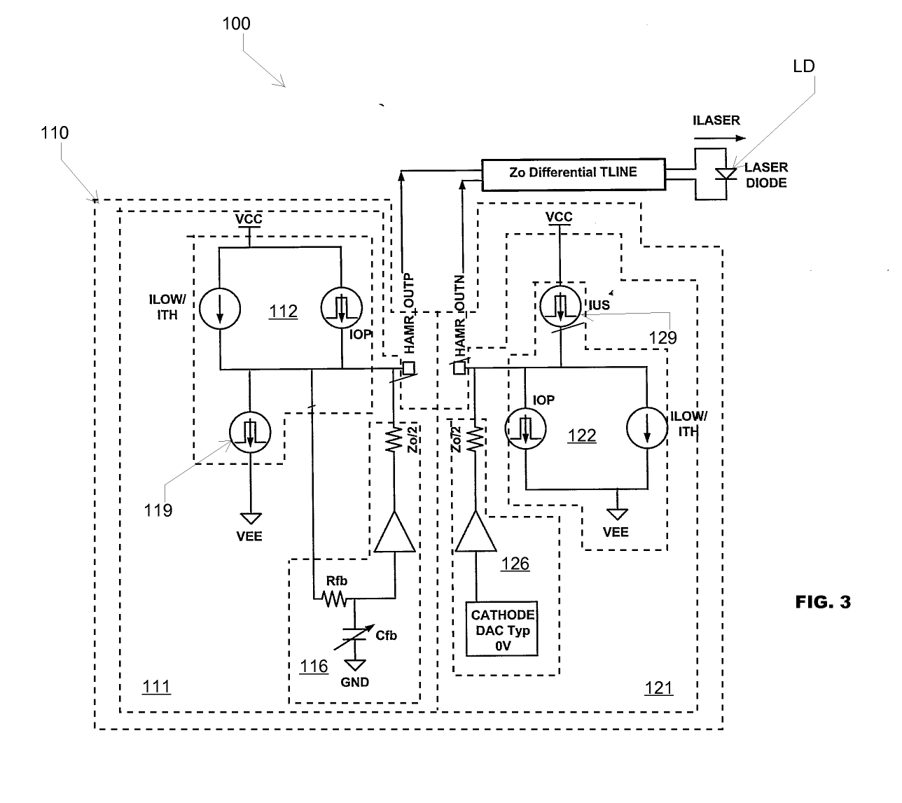

For each write operation, IOP current pulse generator 114, is configured to generate IOP current pulses. As further described in connection with FIG. 3 and the example HAMR waveform in FIG. 4, current drive circuitry 112, including IOP current pulse generator 114, can be configured to provide pulse-shaping with IOS (over-shoot) and IUS (under-shoot). That is, IOP current pulse generator 114 can be configured to provide IOS overshoot, to control rise time of the IOP current pulses, and, as described in connection with FIG. 3, current-drive circuitry 112 can be configured with undershoot circuitry to provide IUS undershoot, to control laser turn-off.

AC-match circuitry 116 is configured as an AC impedance matching loop to provide AC impedance matching to the TLine. In the example embodiment illustrated in FIG. 2, AC-match circuitry 116 is implemented with AC impedance matching circuitry including a driver 117 and resistor Zo/2 connected to the OUTP port, and low-pass Rfb/Cfb filter circuitry 118 that provides a feedback signal to a unity gain buffer 117 to provide impedance matching to the TLine, through a matched resistor Z_{O}/2. Low-pass Rfb/Cfb filter circuitry 118 is configured to low-pass filter the ILASER current from the anode-side current drive circuitry 112 (DC current and IOP current pulses), to generate the feedback control signal to driver 117, providing AC impedance matching to the TLine. For the example embodiment, the Rfb/Cfb filter includes a variable Cfb to provide programmable filter time constant.

DC common-mode-drive and impedance-match circuit 121 is configured to set differential common mode voltage at the laser diode cathode side, impedance matched to the TLine. DC common-mode-drive and impedance-match circuit 121 includes complementary (cathode-side) current source circuitry 122, and DC-match common-mode circuitry 126, both coupled to the OUTN port.

DC-match common-mode circuitry 126 is configured to drive common mode voltage to the laser diode cathode side through a unity gain buffer 127 through a matched resistor Z_{O}/2. Common mode control is provided by a cathode DAC 128 input to buffer 127.

The complementary current source circuitry 122 includes DC current source 123, and IOP current pulse generator 124, parallel coupled to the OUTN port. Current source circuitry 122 is configured as a current source complementary to the anode-side current drive circuitry 112, proving differential common mode voltage accuracy.

LDD 110 is differential impedance-matched, with hybrid AC-DC matching, providing: (1) DC high accuracy current source 113 supplying the standby laser current (ILOW), the low current drive level of the laser when no data is switching; (2) High accuracy pulsing current source 114 supplying the IOP laser operating current using a replica bias DC Loop 116 producing both off and on switching references; (3) Fully differential drive (OUTP/OUTN) over the differential TLine, with bit selectable option for lower power single ended drive; (4) DC Output Impedance Match of the Cathode side of the laser diode LD; (5) AC coupled Output Impedance Match on the Anode side of the laser diode LD, based on feedback low pass filter RfbCfb driving a unity gain buffer 117 and match resistor Z_{O}/2.

LDD 110 is configured for differential drive with DC and AC impedance match: (1) DC Match on Cathode terminal of the Laser Diode LD, and sets the common mode voltage of the differential driver; (2) AC Match on Anode side of the Laser Diode Allows for high accuracy DC current AC-DC match, and allows for both high frequency matching and DC Current accuracy. Differential drive has advantages of lower output capacitance (better high frequency output match), better signal integrity due to elimination of ground loop inductance, and more headroom for driving the interconnect (application has +5/−3V supplies).

That is, LDD 110 uses a hybrid AC-DC match to provide a symmetric drive to the transmission line interconnect leading to the laser diode LD. The method allows for DC accuracy and AC Accuracy.

FIG. 3 illustrates an alternate embodiment of the differential impedance matched laser diode driver with hybrid AC-DC match, including undershoot control for fast laser turn-off. LDD system 110 includes anode-side undershoot-control circuitry 119 coupled to the OUTP port, and cathode-side undershoot-control circuitry 129 coupled to the OUTN port. Anode-side and cathode-side undershoot-control circuitries 119/129 are configured to provide complementary undershoot-control for the IOP current pulses driven to the laser diode, thereby controlling laser turn-off at the end of an IOP current pulse.

FIG. 4 illustrates example HAMR waveforms for write operation in which an IOP current pulse is driven to a laser diode, including overshoot/undershoot pulse shaping. Referring also to FIG. 3 and LDD 110, for write mode, LDD transitions DC current drive from a read mode DC current ITH to a write mode standby DC current ILOW.

For write operations (represented by Write Not Read pin active), IOP current pulses are driven to the laser diode. The example HAMR waveform in FIG. 4 illustrates an example IOP current pulse, such as can be generated by the example LDD 100 in FIG. 3, including IOS (overshoot) and IUS (undershoot) pulse shaping.

As an illustrated design example, an IOP pulse can be characterized by successive DC levels: (1) IOP+IOS; (2) IOP; and (3) IUS. In the illustrated design example, IOS, IOP, IUS are each less than 70 mA, with IOS+IOP less than 105 mA. Example durations are: (1) a total pulse width IOS+IOP in the range of 100-900 ps, with (2) IOS_DUR in the range of 100-500 ps, followed by (3) IUS in the range of 100-500 ps.

Advantages of the Disclosed differential impedance matched laser diode driver with hybrid AC-DC matching include the following. Hybrid AC-DC match provides a symmetric drive to the transmission line interconnect leading to the laser diode. DC and AC impedance match allows for DC accuracy and AC broadband impedance matching, and adds undershoot control for sharp laser turn off. It also eliminates the GND loop inductance from the output drive match circuit. Differential drive provides associated speed and signal integrity advantages. No external components are required (such as inductors, ac coupling capacitors, transformers). High accuracy DC current drive, and high speed AC current drive, with symmetrical drive (for example, to reduce coupling to other HDD head sensors). DC replicate biasing loop in the AC-match circuitry (FIGS. 2/3, 118, 116) provides for more accurate laser output current over process, voltage and temperature.

The Disclosure provided by this Description and the Figures sets forth example embodiments and applications illustrating aspects and features of the invention, and does not limit the scope of the invention, which is defined by the claims. Known circuits, functions and operations are not described in detail to avoid obscuring the principles and features of the invention. These example embodiments and applications can be used by ordinarily skilled artisans as a basis for modifications, substitutions and alternatives to construct other embodiments, including adaptations for other applications.

1. An apparatus, as described herein.

2. An apparatus comprising:
means for differential impedance matched laser diode driving with AC-DC match.
